(19) United States
(12) Patent Application Publication
(10) Pub. No.: US 2024/0155918 A1
(43) Pub. Date: May 9, 2024

(54) DISPLAY APPARATUS

(71) Applicant: LG Display Co., Ltd., Seoul (KR)

(72) Inventor: Sungsik SON, Gumi-si (KR)

(21) Appl. No.: 18/501,315

(22) Filed: Nov. 3, 2023

(30) Foreign Application Priority Data
Nov. 9, 2022 (KR) 10-2022-0148748

(51) Int. Cl. H10K 59/80

(52) U.S. Cl. CPC H10K 59/872

(57) ABSTRACT

A display apparatus in an embodiment comprises a display panel comprising a display area and a non-display area, a cover window being disposed on the display panel, and a back frame being coupled to the cover window, wherein the cover window comprises a plurality of protrusions on a first lateral surface thereof, the back frame comprises a plurality of fixation grooves being coupled to the plurality of protrusions, on a first lateral surface thereof, and the back frame comprises a sliding groove on a second lateral surface thereof, being perpendicular to the first lateral surface, and a third lateral surface thereof, facing the second lateral surface.

### CROSS-REFERENCE TO RELATED APPLICATION

This application claims priority to and benefit of Korean Patent Application No. 10-2022-0148748, filed on Nov. 9, 2022; which is hereby incorporated by reference as if fully set forth herein.

### BACKGROUND

### Technical Field

The present disclosure relates to a display apparatus, and in particular, a display apparatus that ensures improvement on the fixation forces between a back frame and a cover window that comprise sliding grooves and fixation grooves, and ensures a reduction in a bezel area.

### Description of the Related Art

In recent years, display apparatuses displaying various types of information and interacting with a user who watches the information come in different sizes and shapes, and provide various functions.

Typical examples of a display apparatus comprise a liquid crystal display (LCD) device, an electrophoretic display device (EPD), an organic light-emitting diode (OLED) display device, and the like.

Organic light-emitting diode display device emit light by itself, and unlike liquid crystal display (LCD) device, organic light-emitting diode display device does not need an additional light source, and can be manufactured in the form of a thin and lightweight display device. Additionally, an organic light-emitting diode display device is driven at a low voltage, reducing power consumption, embodying colors, ensuring an excellent response speed, an excellent viewing angle and an excellent contrast ratio (CR), and is studied as a next-generation display.

Organic light-emitting diode display device is applied to a wide range of products such as monitors, televisions, mobile phones, display devices for vehicles, and the like.

The organic light-emitting diode display device comprises a display panel displaying an image, and a cover window disposed on the display panel to protect the upper surface of the display panel and reduce the reflection of external light, and the display panel and the cover window are coupled. The organic light-emitting diode display device comprises a back frame reducing an external shock applied to the display panel.

### BRIEF SUMMARY

A cover window may be attached to a back frame with an adhesive or a double-sided tape and the like.

At this time, an adhesive area having a predetermined surface area or greater is needed to ensure the fixation forces between the back frame and the cover window.

Thus, the size of the bezel as the non-display area of a display apparatus, corresponding to the size of the adhesive area, increases.

To solve the problem, the applicants devised a display apparatus ensuring a reduction in the size of a bezel and an increase in fixation force.

The objective of the present disclosure is to provide a display apparatus that ensures a reduction in costs, and ensures ease of fixation of a cover window and a display panel to a back frame, since an adhesive material such as an adhesive or a double-sided tape and the like is not needed.

The objective of the present disclosure is to provide a display apparatus capable of reducing a size of a bezel by minimizing a fixing area where the cover window and the back frame are coupled to each other and capable of improving a fixation force between a cover window and a back frame.

A display apparatus in an embodiment comprises a display panel comprising a display area and a non-display area, a cover window being disposed on the display panel, and a back frame being coupled to the cover window. The cover window may comprise a plurality of protrusions on a first lateral surface thereof, and the back frame may comprise a plurality of fixation grooves being coupled to the plurality of protrusions, on a first lateral surface thereof. The back frame may comprise a sliding groove on a second lateral surface thereof, being perpendicular to the first lateral surface, and a third lateral surface thereof, facing the second lateral surface.

Other particulars of embodiments are provided in the detailed description and the drawings.

In a display apparatus according to an embodiment of the present disclosure, a plurality of protrusions may be formed on a first lateral surface of a cover window that is attached to the upper portion of a display panel, and may be coupled to a plurality of fixation grooves of a first lateral surface of a back frame. Additionally, a second lateral surface of the back frame, being perpendicular to the first lateral surface thereof, and a third lateral surface of the back frame, facing the second lateral surface thereof, may have a sliding groove, and a second lateral surface of the cover window, being perpendicular to the first lateral surface thereof, and a third lateral surface of the cover window, facing the second lateral surface thereof, may be coupled to the sliding grooves of the back frame. Due to this structure, the back frame and the cover window may be coupled readily without an adhesive material.

Additionally, by coupling the back frame and the cover window using the fixation grooves and the sliding grooves, the fixation area can be minimized and the size of the bezel can be reduced.

A fixation bar disposed in the lower portion of a fourth lateral surface of the cover window, facing the first lateral surface thereof, may be coupled to a lower end fixation part disposed in the lower portion of a fourth lateral surface of the back frame, facing the first lateral surface thereof, to fix the first, second, third and fourth lateral surfaces of the cover window and the back frame. Thus, the fixation force between the cover window and the back frame may be secured despite vibrations and a shock of the display apparatus.

Aspects according to the present disclosure are not limited to the above ones, and other aspects and advantages that are not mentioned above can be clearly understood from the following description by one having ordinary skill in the art.

Since particulars described in the above technical problems, technical solutions and advantageous effects do not specify essential features in the claims, the scope of the right to the claims in the disclosure is not limited by the particulars described in the summary.

### BRIEF DESCRIPTION OF THE SEVERAL VIEWS OF THE DRAWINGS

The accompanying drawings constitute a part of the specification, illustrate one or more embodiments in the disclosure, and together with the specification, explain the disclosure, wherein:

FIG. 1 is an exploded perspective view showing a display apparatus of one embodiment;

FIG. 2 is a plan view showing a back frame of the display apparatus of one embodiment;

FIG. 3 is an enlarged view showing a portion of FIG. 2;

FIG. 4 is a perspective view showing that a portion of FIG. 2 is half-permeated;

FIG. 5a is a perspective view showing a cover window of the display apparatus of one embodiment;

FIG. 5b is an enlarged view showing a portion of 5a;

FIG. 6a is a perspective view showing the back frame of the display apparatus of one embodiment;

FIG. 6b is an enlarged view showing a portion of FIG. 6a;

FIG. 7a is a perspective view showing a coupling of the back frame and the cover window of the display apparatus of one embodiment;

FIG. 7b is a perspective view showing a fourth lateral surface of FIG. 7a;

FIG. 7c is an enlarged view showing a portion of FIG. 7b;

FIG. 8 is a plan view showing the display apparatus of one embodiment; and

FIG. 9 is a cross-sectional view showing an example of the cross section of D-D′ in FIG. 8.

### DETAILED DESCRIPTION

Advantages and features in the present disclosure and a method of ensuring the same can be clearly understood from embodiments that are described hereafter with reference to accompanying drawings. The subject matter of the disclosure, however, can be embodied in various different forms, and should not be construed as being limited to the embodiments set forth herein. Rather, the embodiments are provided as examples so that the disclosure can be thorough and complete and can fully convey the scope of the disclosure to one having ordinary skill in the art.

The shapes, sizes, ratios, angles, number and the like of the components illustrated in the drawings provided for describing the embodiments of the disclosure are given only as examples, and the subject matter of the disclosure is not limited by the particulars in the drawings. Throughout the disclosure, like reference numerals denote like components. In describing the subject matter, detailed description of well-known technologies relevant to the disclosure is omitted if it is deemed to make the gist of the disclosure unnecessarily vague. Throughout the disclosure, terms such as “comprise,” “have,” “being comprised of” and the like are to imply the inclusion of any other component, but for a term such as “only.” Further, the singular forms “a,” “an” and “the” are intended to include the plural forms as well, unless explicitly stated otherwise.

In describing a component, the margin of error is to be included, though not explicitly described.

When spatial terms such as “on,” “in an upper portion,” “under,” “in a lower portion,” “being adjacent to” and the like are used to describe a position relationship between two components, one or more additional components can be interposed between the two components unless a term such as “right” or “directly” is used.

When temporal terms such as “after,” “next,” “following,” “before” and the like are used to describe a temporal order, one or more additional events can be interposed between two events unless a term such as “right” or “directly” is used.

In describing components, terms such as first, second and the like can be used. These terms are only intended to distinguish one component from another component, and the components are not limited by such terms. Certainly, a first component mentioned hereafter can be a second component within the technical spirit of the disclosure.

Terms such as first, second, A, B, (a), (b) and the like are used herein only to distinguish one component from another component. Thus, the essence, order, sequence or number and the like of the components should not be limited by the terms. When any one component is described as being “coupled,” or “connected” to another component, any one component can be directly connected or coupled to another component, but unless stated explicitly, an additional component can be “interposed” between the two components that can be indirectly connected or coupled.

A term such as “at least one” is to be understood as comprising one or more combinations of relevant components. For example, “at least one of a first component, a second component, and a third component” may denote all combinations of two or more of the first component, the second component and the third component, as well as the first component, the second component, or the third component.

In the present disclosure, the “apparatus” may comprise a display panel, and a display apparatus such as a liquid crystal module (LCM) and an organic light-emitting display module (OLED Module) that comprise a driving part for driving the display panel. Additionally, the apparatus may comprise a set electronic apparatus or a set apparatus (or a set device) such as a laptop, a television, a computer monitor, an automotive apparatus, a mobile electronic apparatus a smart phone or an electronic pad and the like that are complete products or final products comprising an LCM, an OLED module and the like.

The apparatus according to the present disclosure may comprise a display apparatus itself such as an LCM, an OLED module and the like, and an application product or a set apparatus as a final consumer apparatus that comprises an LCM, an OLED module and the like.

In several embodiments, a LCM and an OLED module, which are comprised of a display panel, a driving part and the like, may be expressed as a ‘display apparatus,’ and an electronic device as a final product comprising an LCM and an OLED module may be expressed as a ‘set apparatus.’ For example, the display apparatus may comprise a display panel of a liquid crystal display (LCD) or an organic light-emitting diode (OLED), and a source PCB that is a controller for driving a display panel. The set apparatus may further comprise a set PCB that is a set controller connecting to a source PCB electrically and driving a set apparatus entirely.

A display panel in the embodiment may comprise all types of display panels including a liquid crystal display panel, an organic light-emitting diode (OLED) display panel, an electroluminescent display panel and the like, but not be limited. For example, the display panel may be a display panel that may vibrate because of a vibration device in the embodiment and make a sound. The shape or size of the display panel that is applied to the display apparatus in the embodiment is not limited.

Features of the embodiments of the disclosure can be partially or entirely mixed or combined, and can technically link and operate in various ways. Further, each embodiment can be embodied independently, or in connection with each other.

Hereafter, the embodiments of the present disclosure are described as follows, with reference to the accompanying drawings and embodiments. The scales of the components illustrated in the drawings are difference from actual scales for convenience of description, and their scales are not limited to the scales in the drawings.

Hereafter, various embodiments in the disclosure are described with reference to the drawings.

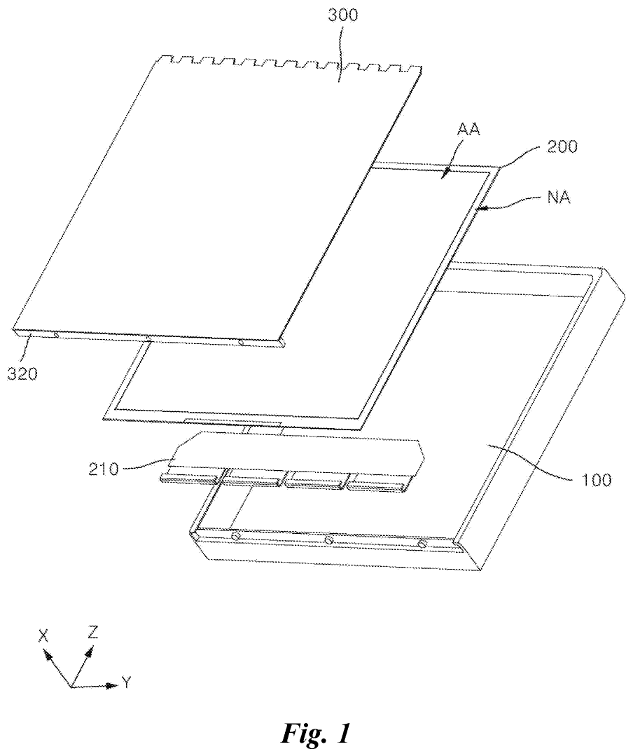

FIG. 1 is an exploded perspective view showing a display apparatus according to one embodiment of the present disclosure.

The display apparatus according to one embodiment may comprise a back frame 100, a display panel 200, a driving assembly 210 and a cover window assembly 300.

The display panel 200 may comprise a plurality of areas. For example, the display panel 200 comprises one or more of display areas AA in which a image is displayed, and has a pixel array in the display area AA. A driving circuit part and a dam part are included in one or more of non-display areas NA in which an image is not displayed, and the non-display area NA may be provided on one lateral surface of the display area AA. For example, the non-display area NA may be adjacent to one or more of side surfaces of the display area AA.

Referring to FIG. 1, the non-display area NA may be disposed outside the display area AA having a rectangle shape while surrounding the display area AA. However, it is to be understood that the shapes of the display area AA and the arrangement of the non-display area NA adjacent to the display area AA are not limited to those of the exemplary display panel 200 illustrated in FIG. 1. The shapes and arrangements of the display area AA and the non-display area NA may vary depending on what shape the display panel 200 has. The shapes may comprise a pentagon, a hexagon, a circle, an oval and the like, for example, but not be limited.

Each of the pixels of the display area AA may comprise sub pixels, and the sub pixels may display colors such as red R, green G, blue B, white W and the like. Additionally, each of the sub pixels may relate to a pixel circuit comprising one or more of TFTs that are manufactured on a substrate of the display apparatus. Each of the pixel circuits may electrically connect to a gate line and a data line, to communicate with one or more of driving circuits, e.g., a gate driver and a data driver that are disposed in the non-display area NA of the display panel 200.

One or more of the driving circuits may be embodied as TFTs that are provided in the non-display area NA, as illustrated in FIG. 1. For example, the gate driver may also be embodied with the plurality of TFTs on the substrate of the display panel 200. Examples of circuits embodied as TFTs on a substrate may comprise an inverter circuit, a multiplexer, and an electro static discharge (ESD) circuit and the like, but not be limited to the above-mentioned examples.

Some driving circuits may be provided as an integrated circuit (IC) chip, and electrically connect to the non-display area NA of the display panel 200 by using chip on glass (COG) or another similar method. The above-described driving circuits may be embodied with a printed circuit board such as a flexible PCB (FPCB), a chip on film (COF) or a tape carrier package (TCP). An assembly comprising the driving circuit can be referred to as a driving assembly 210. The driving assembly 210, for example, may comprise a printed circuit board and a chip on film. The driving assembly 210 may electrically connect to a connection interface (pads/bumps, pins) that is disposed in the non-display area NA of the display panel 200.

The cover window 300 may be attached to the upper portion of the display panel 200, protect the display panel 200, adjust a viewing angle and reduce the reflection of external light.

The cover window 300 may comprise a transparent substrate or a transparent film and an optical film. The optical film, for example, may be a polarization film an anti reflection film (an AR film) or an anti glare film (an AG film), and attached to the entire surface of a transparent substrate 510.

The back frame 100 may be disposed under the display panel 200 and coupled to the cover window 300 to which the display panel 200 is attached.

The driving assembly 210 electrically connecting to the display panel 200 may be disposed between the back frame 100 and the display panel 200, and disposed in the back frame 100.

A plurality of protrusions may be formed and disposed on a first lateral surface of the cover window 300, and a fixation bar 320 attached to the lower portion of the cover window 300 may be disposed on a fourth lateral surface that faces the first lateral surface.

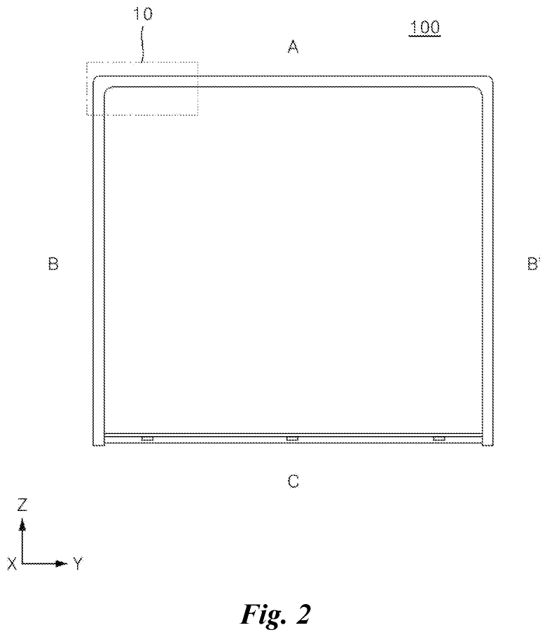

FIG. 2 is a plan view showing a back frame 100 of the display apparatus according to one embodiment.

Referring to FIG. 2, the back frame 100 is illustrated as a substantially rectangular shape. However, in FIG. 2, the shape of the back frame 100 is illustrated as an example. It is to be understood that the shape of the back frame 100 is not limited. The back frame 100 may have any shape. For example, the shape of the back frame 100 may comprise a pentagon, a hexagon, a circle, an oval and the like, but not be limited.

The back frame 100 may be made of a plastic material. For example, the back frame 100 may be made of one of polycarbonate or acrylonitrile butadiene styrene (ABS), but not limited. Additionally, the back frame 100 may be manufactured in a molding process.

The upper portion of the back frame 100 is formed in an open shape corresponding to the display area AA of the display panel 200, and be coupled to the cover window 300, such that the display panel 200 and the driving assembly 210 are stored or accommodated in the back frame 100.

The back frame 100 may have a first lateral surface A in the Z-axis direction, a second lateral surface B perpendicular to the first lateral surface and in the Y-axis direction, a third lateral surface B′ facing the second lateral surface B, and a fourth surface C facing the first lateral surface A.

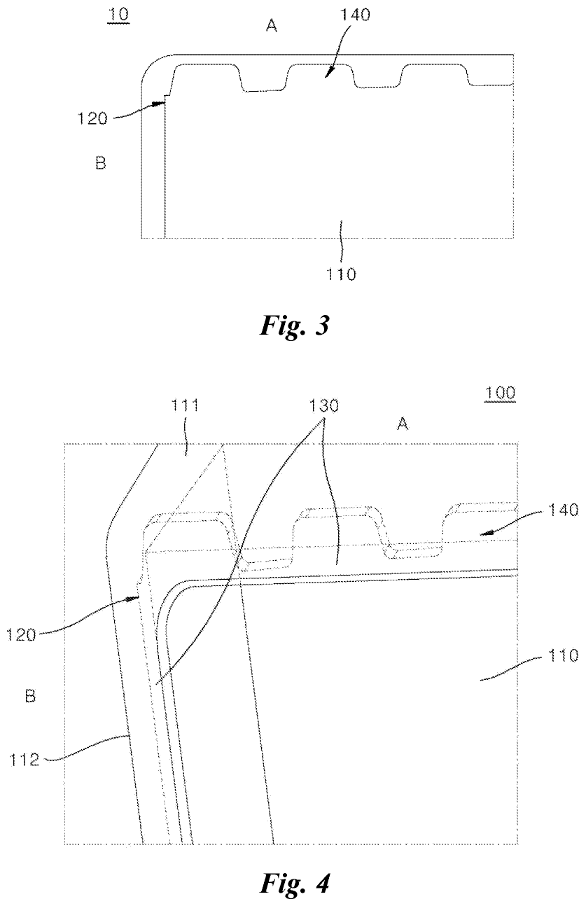

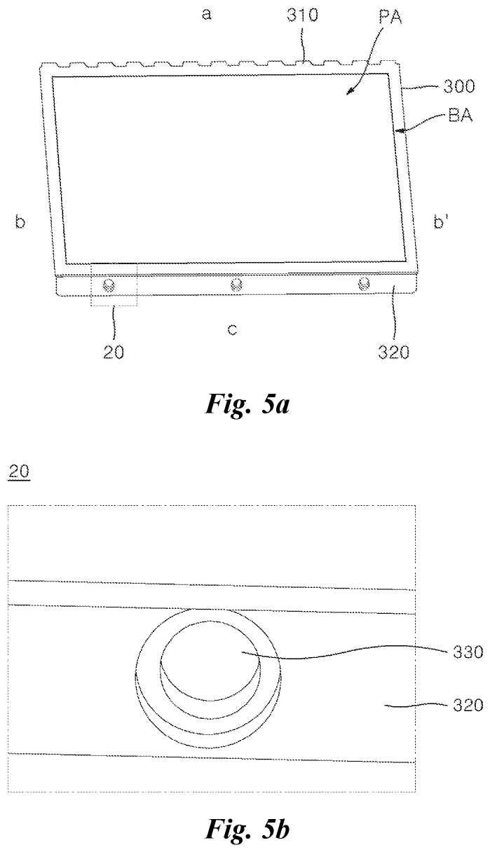

FIG. 3 is an enlarged view showing a portion of FIG. 2, and FIG. 4 is a perspective view showing a portion of FIG. 2 in a semi-transparent manner.

Referring to FIGS. 3 and 4, a first lateral wall 111 of the first lateral surface A may be elongated upward from a bottom surface 110 of the back frame 100, and a plurality of fixation grooves 140 may be formed on the first lateral wall 111 of the first lateral surface A.

The plurality of fixation grooves 140 may be formed on the first lateral surface A, in the form of a trapezoid. Each of the plurality of fixation grooves 140 may be formed to have the same size and shape, but not limited.

A sliding groove 120 may be respectively formed on second lateral walls 112 of the second lateral surface B and the third lateral surface B′, along the second lateral surface B and the third lateral surface B′.

An upper surface part 130 may be elongated from the first lateral wall 111 and the second lateral wall 112 of the back frame 100, and cover the plurality of fixation grooves 140 and sliding grooves 120.

The cover window 300 is fitted and coupled to the plurality of fixation grooves 140 and sliding grooves 120. Since the upper surface part 130 may be wider than the plurality of fixation grooves 140 and sliding grooves 120, the plurality of fixation grooves 140 and sliding grooves 120 may not seen in a plan view. Additionally, the upper surface part 130 may prevent the cover window 300 from moving in the X-axis direction.

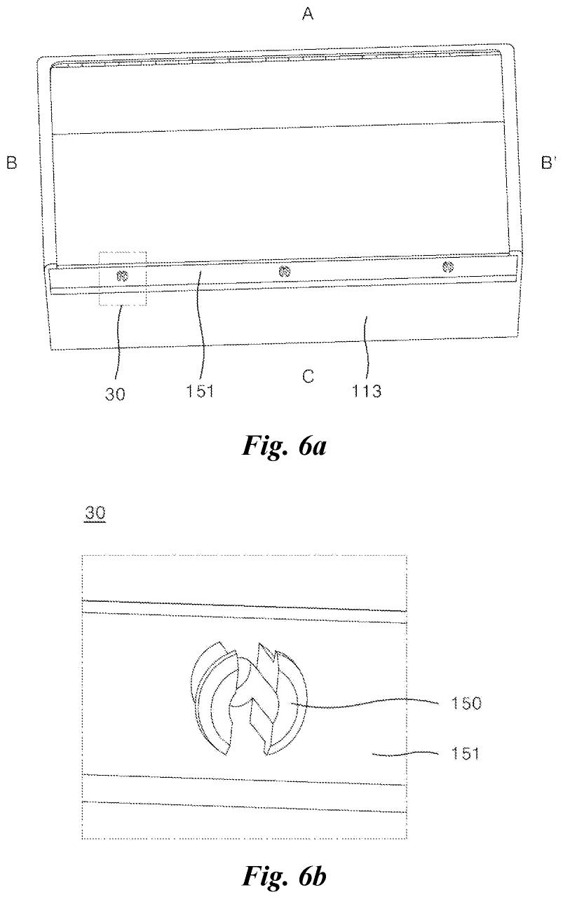

FIG. 5a is a perspective view showing a cover window of the display apparatus according to one embodiment of the present disclosure, and FIG. 5b is an enlarged view showing a portion 20 of FIG. 5a.

The cover window 300 may comprise a panel area PA to which the display panel 200 is attached, and a bezel area BA which is disposed outside the panel area PA, and the first lateral surface a of the cover window 300 may comprise a plurality of protrusions 310.

The plurality of protrusions 310 may be shaped into a trapezoid, but not limited. The plurality of protrusions 310 may be fitted and coupled to the fixation groove 140 of the back frame 100.

The second lateral surface b being perpendicular to the first lateral surface a and the third lateral surface b′ facing the second lateral surface b of the cover window 300 may be fitted and connected to the sliding groove 120 of the back frame 100 or coupled to the sliding groove 120 of the back frame 100, thereby preventing the Y-axis movement of the cover window 300.

A fixation bar 320 may be disposed on the lower surface of the fourth lateral surface C facing the first lateral surface a of the cover window 300.

The fixation bar 320 may be made of a material such as polycarbonate (PC) or polymethyl methacrylate (PMMA) and the like, but not limited. The fixation bar 320 may be attached and fixed to the lower surface of the cover window 300, with an adhesive, a double-sided tape or based on thermal welding, but not limited.

The fixation bar 320 may have at least one or more of fixation holes 330. At least one or more of the fixation holes 330 may be shaped into a two-staged hole, but not limited.

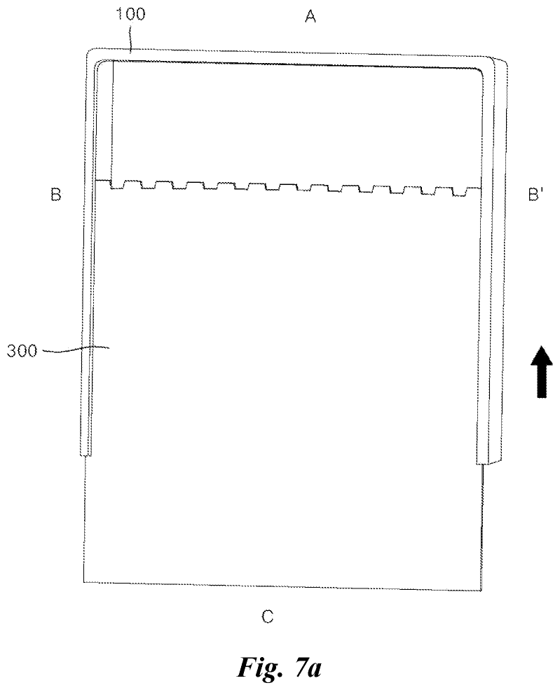

FIG. 6a is a perspective view showing the back frame of the display apparatus according to one embodiment of the present disclosure. FIG. 6b is an enlarged view showing a portion 30 of FIG. 6a.

A lower end fixation part 151 may be disposed in a portion of the fourth lateral surface C of the back frame 100. The lower end fixation part 151 may be formed in a portion of the outer side of the third lateral wall 113 that is elongated upward from the bottom surface 110 of the back frame 100.

The lower end fixation part 151 may form a step that has a width and a thickness corresponding to the width and the thickness of the fixation bar 320 of the cover window 300, on the fourth lateral surface C of the back frame 100. Accordingly, as the fixation bar 320 of the cover window 300 and the fourth lateral surface C of the back frame 100 are coupled, the fixation bar 320 of the cover window 300 may form a planar surface, together with the fourth lateral surface C of the back frame 100.

The thickness of the lower end fixation part 151 may be less than the thickness of the fourth lateral surface C of the back frame 100, on which the lower end fixation part 151 is not formed.

At least one or more of hooks 150 may be disposed or formed at the lower end fixation part 151. At least one or more of the hooks 150 may be shaped into a circular hook, but not limited.

At least one or more of the hooks 150 may be coupled to at least one or more of the fixation holes 330 of the fixation bar 320 to fix the cover widow 300.

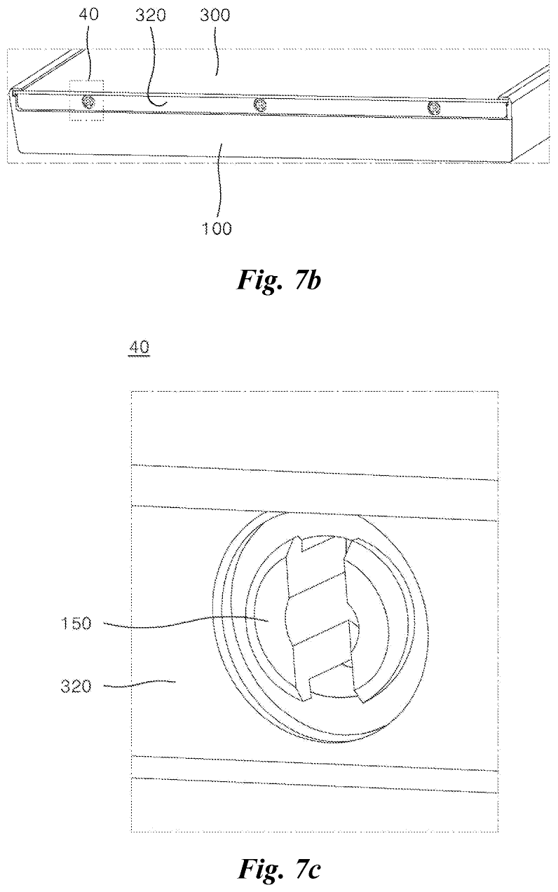

FIG. 7a is a perspective view showing a coupling of the back frame and the cover window of the display apparatus according to one embodiment of the present disclosure.

FIG. 7b is a perspective view showing a fourth lateral surface of FIG. 7a, and FIG. 7c is an enlarged view showing a portion of FIG. 7b.

Referring to FIG. 7a, the cover window 300 may be fitted and inserted into the sliding grooves 120 of the second lateral surface B and the third lateral surface B′ of the back frame 100 in the direction of the fourth lateral surface C of the back frame 100.

Referring to FIG. 7b and FIG. 7c, at least one or more of the hooks 150 of the lower end fixation part 151 of the back frame 100 may be coupled to at least one or more of the fixation holes 330 of the fixation bar 320 that is attached to the lower surface of the cover window 300, and the fixation bar 320 may be fixed to the lower end fixation part 151 in contact with the lower end fixation part 151.

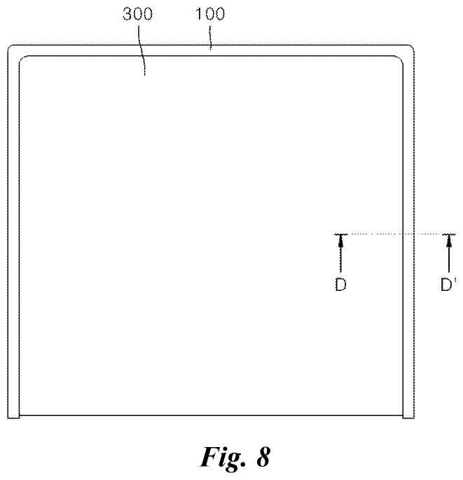

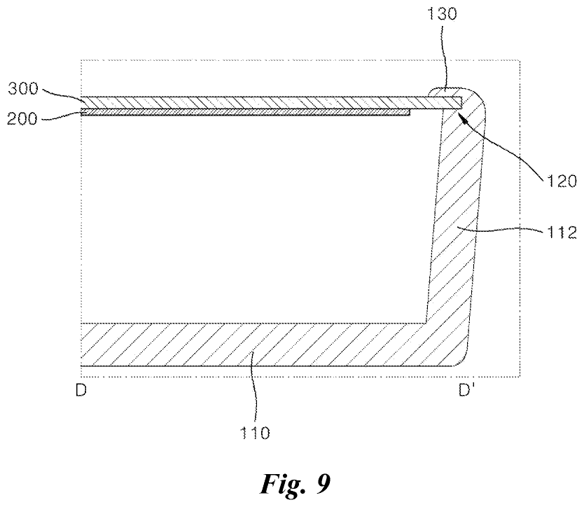

FIG. 8 is a plan view showing the display apparatus according to one embodiment of the present disclosure, and FIG. 9 is a cross-sectional view showing an example of the cross section of D-D′ in FIG. 8

Referring to FIGS. 8 and 9, as the back frame 100 and the cover window 300 are coupled, the upper portions of the first lateral surface a, second lateral surface b and third lateral surface b′ of the cover window 300 may partially overlap the upper surface part 130 of the back frame 100.

The display panel 200 attached to the lower portion of the cover window 300 may be disposed inside the back frame without overlapping the upper surface part 130 of the back frame 100.

The plurality of protrusions 310 of the first lateral surface a of the cover window 300 may be coupled to the plurality of fixation grooves 140 of the first lateral surface A of the back frame 100. The second lateral surface b and the third lateral surface b′ of the cover window 300 maybe coupled to the sliding grooves 120 of the second lateral surface B and the third lateral surface B′ of the back frame 100. At least one or more of the fixation holes 330 of the fixation bar 320 attached to the lower surface of the fourth lateral surface c of the cover window 400 may be coupled to the at least one or more of the hooks 150 of the lower end fixation part 151 of the fourth lateral surface C of the back frame 100.

All the four lateral surfaces of the cover window 300 may be coupled to the four lateral surfaces of the back frame 100, thereby securing the fixation forces of the cover window 300 and the back frame 100 despite external vibrations and an external shock.

The display apparatus in the embodiment is described as follows.

The display apparatus in the embodiment comprises a display panel comprising a display area and a non-display area, a cover widow being disposed on the display panel, and a back frame being coupled to the cover window, the cover window comprises a plurality of protrusions on the first lateral surface thereof, the back frame comprises a plurality of fixation grooves, which is coupled to the plurality of protrusions, on the first lateral surface thereof, and the back frame comprises a sliding groove on the second lateral surface thereof, which is perpendicular to the first lateral surface thereof, and on the third lateral surface thereof, which faces the second lateral surface.

In several embodiments, a second lateral surface of the cover window being perpendicular to the first lateral surface, and a third lateral surface of the cover window facing the second lateral surface may be coupled to the sliding grooves of the second lateral surface and the third lateral surface of the back frame.

In several embodiments, the plurality of fixation grooves and the sliding grooves of the back frame may be provided on the lateral walls that are elongated upward from the bottom surface of the back frame.

In several embodiments, the upper surface part may be further included, and may be elongated from the lateral walls of the back frame and cover the plurality of fixation and the sliding grooves.

In several embodiments, the fixation bar may be disposed on the lower surface of the fourth lateral surface facing the first lateral surface of the cover window.

In several embodiments, the fourth lateral surface facing the first lateral surface of the back frame may comprise a lower end fixation part having at least one or more of hooks.

In several embodiments, the lower end fixation part may be provided in a portion of the fourth lateral surface, and the thickness of the lower end fixation part may be less than the thickness of the fourth lateral surface.

In several embodiments, the fixation bar may comprise at least one or more of fixation holes, and at least one or more of the hooks may be coupled to at least one or more of the fixation holes.

In several embodiments, at least one or more of the fixation holes may be a two-staged circular hole, and at least one or more of the hooks may be a circular hook.

In several embodiments, the fixation bar may be attached to the lower surface of the fourth lateral surface of the cover window, by using one of an adhesive, a double-sided tape, and thermal welding.

In several embodiments, a driving assembly comprising a printed circuit board and a chip on film may connect to the display panel electrically.

In several embodiments, the driving assembly may be disposed between the back frame and the display panel.

The embodiments of the present disclosure are described above with reference to the accompanying drawings. However, embodiments are not limited to the embodiments set forth herein, and can be modified in various different forms within the technical spirit of the disclosure. It is to be understood that the embodiments set forth herein are provided as examples to describe the technical spirit of the disclosure rather than limiting the technical spirit of the disclosure and are not intended to limit the scope of the technical spirit.

### DESCRIPTION OF REFERENCE NUMERALS

A: First lateral surface
B: Second lateral surface
B′: Third lateral surface
C: Fourth lateral surface
100: Back frame
110: Bottom surface
111: First lateral wall
112: Second lateral wall
120: Sliding groove
130: Upper surface part
140: Fixation groove
150: Hook
151: Lower end fixation part
200: Display panel
300: Cover window
310: Protrusion
320: Fixation bar
330: Fixation hole

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel including a display area and a non-display area;
a cover window disposed on the display panel; and
a back frame coupled to the cover window, wherein:
the cover window includes a plurality of protrusions on a first lateral surface of the cover window,
the back frame includes a plurality of fixation grooves on a first lateral surface of the back frame, the plurality of fixation grooves coupled to the plurality of protrusions of the cover window, and
the back frame includes a sliding groove on a second lateral surface and a third lateral surface of the back frame, the second lateral surface being perpendicular to the first lateral surface of the back frame, and the third lateral surface facing the second lateral surface.

2. The display apparatus of claim 1, wherein the cover window includes a second lateral surface being perpendicular to the first lateral surface of the cover window, and the cover window further includes a third lateral surface facing the second lateral surface, wherein the second lateral surface and the third lateral surface of the cover window are coupled to the sliding grooves of the second lateral surface and the third lateral surface of the back frame.

3. The display apparatus of claim 1, wherein the plurality of fixation grooves and the sliding grooves of the back frame are provided on a lateral wall of the back frame, wherein the lateral wall is elongated upward from a bottom surface of the back frame.

4. The display apparatus of claim 3, wherein the display apparatus further comprises an upper surface part, wherein the upper surface part is elongated from the lateral wall of the back frame and covers the plurality of fixation grooves and the sliding grooves.

5. The display apparatus of claim 1, wherein cover window includes a fixation bar disposed on a lower surface of a fourth lateral surface of the cover window, and wherein the fourth lateral surface of the cover window faces the first lateral surface of the cover window.

6. The display apparatus of claim 5, wherein the back frame further includes a lower end fixation part having at least one hook on a fourth lateral surface of the back frame, the fourth lateral surface of the back frame facing the first lateral surface of the back frame.

7. The display apparatus of claim 6, wherein the lower end fixation part is provided in a portion of the fourth lateral surface of the back frame, and a thickness of the lower end fixation part is less than a thickness of the fourth lateral surface of the back frame.

8. The display apparatus of claim 6, wherein the fixation bar includes at least one fixation hole, and
the at least one hook is coupled to the at least one fixation hole.

9. The display apparatus of claim 8, wherein the at least one fixation hole is a two-staged circular hole, and
the at least one hook is a circular hook.

10. The display apparatus of claim 5, wherein the fixation bar is attached to the lower surface of the fourth lateral surface of the cover window, by one of an adhesive, a double-sided tape, and thermal welding.

11. The display apparatus of claim 1, further comprising:
a driving assembly including a printed circuit board and a chip on film electrically coupled to the display panel.

12. The display apparatus of claim 11, wherein the driving assembly is disposed between the back frame and the display panel.

13. A display apparatus, comprising:
a display panel;
a cover window disposed on the display panel, the cover window including a plurality of protrusions; and
a back frame coupled to the cover window, the back frame including a plurality of fixation grooves and at least sliding groove,
wherein the plurality of fixation grooves and the at least one sliding groove are on different surfaces of the back frame, and
wherein the plurality of protrusions of the cover window are coupled to the plurality of fixation grooves of the back frame.

14. The display apparatus of claim 13, wherein the at least one sliding groove of the back frame includes a first sliding groove and a second sliding groove, the first sliding groove and the second sliding groove being on opposite lateral surfaces of the back frame.

15. The display apparatus of claim 14, wherein the cover window includes opposite side surfaces coupled to the first sliding groove and the second sliding groove on the opposite lateral surfaces of the back frame.

16. The display apparatus of claim 14, wherein the back frame includes a lateral wall extending from a bottom surface of the back frame, the lateral wall including the plurality of fixation grooves, the first sliding groove, and the second sliding groove.

17. The display apparatus of claim 13, wherein the back frame further includes a fastener having a hook, and wherein the fastener is located on an opposite side of the back frame from the plurality of fixation grooves.

18. The display apparatus of claim 17, wherein the cover window includes a fixation bar with a hole configured to receive the hook of the fastener of the back frame.

19. The display apparatus of claim 13, further comprising:
a driving assembly electrically coupled to the display panel and disposed between the back frame and the display panel, wherein the driving assembly includes a printed circuit board and a chip on film.
